(19) United States
(12) Patent Application Publication
(10) Pub. No.: US 2025/0266244 A1
(43) Pub. Date: Aug. 21, 2025

(54) PLASMA LAYER DEPOSITION APPARATUS AND METHOD OF PREDICTING THICKNESS PROFILE OF LAYER

(71) Applicant: SAMSUNG ELECTRONICS CO., LTD., Suwon-si (KR)

(72) Inventors: Kyoungmi CHOI, Suwon-si (KR); Youngjoon OH, Suwon-si (KR); Jaeeun LEE, Suwon-si (KR); Taeki HONG, Suwon-si (KR)

(73) Assignee: SAMSUNG ELECTRONICS CO., LTD., Suwon-si (KR)

(21) Appl. No.: 19/052,723

(22) Filed: Feb. 13, 2025

(30) Foreign Application Priority Data
Feb. 20, 2024 (KR) 10-2024-0024338

(51) Int. Cl. H01J 37/32

(52) U.S. Cl. CPC H01J 37/32183; H01J 37/32926; H01J 37/32935; H01J 2237/3321

(57) ABSTRACT

A method of predicting a thickness profile of a layer includes providing a plasma layer deposition apparatus, loading a wafer on a substrate stage, where the wafer includes a first region having a first material and a second region having a second material, deriving an equivalent circuit model of a plasma system simulating the plasma layer deposition apparatus, determining a sheath voltage based on the equivalent circuit model, the sheath voltage corresponding to a voltage applied to a space adjacent to the wafer by a matcher current from an impedance matcher, and predicting a selectivity of the layer as a ratio between a first thickness of a first deposition portion on the first region and a second thickness of a second deposition portion on the second region based on a correlation between the determined sheath voltage and a pre-stored selectivity value.

### CROSS-REFERENCE TO RELATED APPLICATION

This application is based on and claims priority to Korean Patent Application No. 10-2024-0024338, filed on Feb. 20, 2024, in the Korean Intellectual Property Office (KIPO), the disclosure of which is incorporated herein by reference in its entirety.

### BACKGROUND

Example embodiments of the disclosure relate to a plasma layer deposition apparatus and a method of predicting a thickness profile of a layer using the same, and more particularly, to a method of predicting a structure of a layer deposited on a silicon wafer.

In a layer deposition process, plasma enhanced chemical vapor deposition (PECVD) may be applied. In this case, it may be required to predict a structure of a deposited layer using a simulation in order to minimize trial and error. For example, it may be required to predict selectivity because the selectivity with respect to an underlying material is an important factor in order to decrease a feature scale of a semiconductor device and a resistance of a semiconductor device.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a plasma thin film deposition apparatus capable of predicting a selectivity of a thin film that will be formed by a deposition process, and a method of predicting a thin film by using the plasma thin film deposition apparatus.

Additional aspects will be set forth in part in the description which follows and, in part, will be apparent from the description, or may be learned by practice of the presented embodiments.

According to an aspect of an example embodiment, a method of predicting a thickness profile of a layer may include providing a plasma layer deposition apparatus, where the plasma layer deposition apparatus includes a substrate stage provided in a chamber, a lower electrode, an upper electrode, and a source power circuit including a high frequency generator and an impedance matcher configured to supply a radio frequency (RF) power to the upper electrode, loading a wafer on the substrate stage, where the wafer includes a first region having a first material and a second region having a second material, deriving an equivalent circuit model of a plasma system simulating the plasma layer deposition apparatus, determining a sheath voltage based on the equivalent circuit model, the sheath voltage corresponding to a voltage applied to a space adjacent to the wafer by a matcher current from the impedance matcher, and predicting a selectivity of the layer as a ratio between a first thickness of a first deposition portion on the first region and a second thickness of a second deposition portion on the second region based on a correlation between the determined sheath voltage and a pre-stored selectivity value.

According to an aspect of an example embodiment, a method of predicting a thickness profile of a layer may include providing a plasma layer deposition apparatus, where the plasma layer deposition apparatus includes a chamber, a substrate stage provided in the chamber, a lower electrode, an upper electrode, a source power circuit including a high frequency generator and an impedance matcher configured to supply an RF power to the upper electrode, and an impedance controller configured to control a current flowing to the lower electrode, loading a wafer on the substrate stage, deriving an equivalent circuit model of a plasma system simulating the plasma layer deposition apparatus, determining a sheath voltage based on the equivalent circuit model, the sheath voltage corresponding to a voltage applied to a space adjacent to the wafer by a matcher current from the impedance matcher, and predicting a selectivity as a ratio between thicknesses of each of plurality of deposition portions of the layer to be formed on the wafer based on a correlation between the determined sheath voltage and a pre-stored selectivity value.

According to an aspect of an example embodiment, a method of predicting a thickness profile of a layer may include providing a plasma layer deposition apparatus, where the plasma layer deposition apparatus includes a chamber including a plasma region where plasma is formed and a plurality of sheath regions surrounding the plasma region, a substrate stage in the chamber, a lower electrode, an upper electrode configured, and a source power circuit including a high frequency generator and an impedance matcher configured to supply an RF power to the upper electrode, loading a wafer on the substrate stage, where the wafer includes a first region having a first material and a second region having a second material, deriving an equivalent circuit model of a plasma system simulating the plasma layer deposition apparatus, determining a sheath voltage based on the equivalent circuit model, the sheath voltage corresponding to a voltage applied to a space adjacent to the wafer by a matcher current from the impedance matcher, and predicting a selectivity of the layer as a ratio between a first thickness of a first deposition portion to be formed on the first region and a second thickness of a second deposition portion to be formed on the second region based on the determined sheath voltage and a pre-stored selectivity value.

According to an aspect of an example embodiment, a plasma layer deposition apparatus may include a chamber including a process space and a gas supplier configured to supply a gas in the process space, a substrate stage in the chamber and configured to load a wafer, where the wafer includes a first region including a first material and a second region including a second material, a plasma control portion including a lower electrode provided in the substrate stage, an upper electrode provided on the chamber and configured to form a plasma between the lower electrode and the upper electrode, and a source power circuit including a high frequency generator and an impedance matcher configured to supply a radio frequency power to the upper electrode, and a simulation module configured to predict a selectivity of a layer deposited on the wafer, where the chamber includes a plasma region between the wafer and the upper electrode, and a plurality of sheath regions surrounding the plasma region, the simulation module is configured to derive an equivalent circuit model of a plasma system simulating the plasma layer deposition apparatus, and to predict the selectivity based on the equivalent circuit model, and the selectivity is a ratio between a first thickness of a first deposition portion on the first region and a second thickness of a second deposition portion on the second region.

According to example embodiments, in a method of predicting a thickness profile of a layer, a plasma layer deposition apparatus is provided, wherein the plasma layer deposition apparatus includes a substrate stage provided in a chamber and having a lower electrode, an upper electrode configured to form plasma between the upper electrode and the lower electrode, and a source power circuit having a high frequency generator and an impedance matcher configured to supply a radio frequency (RF) power to the upper electrode. A wafer is loaded, wherein the wafer includes a first region having a first material and a second region having a second material. An equivalent circuit model is derived, wherein the equivalent circuit model corresponds to a plasma system including the high frequency generator and the impedance matcher. A sheath voltage based on the equivalent circuit model is determined, wherein the sheath voltage is applied to a space adjacent the loaded wafer by a matcher current from the impedance matcher. A selectivity of the layer as a ratio between a first thickness of a first deposition portion to be formed on the first region and a second thickness of the second deposition portion to be formed on the second region is predicted by using relation between the determined sheath voltage and the selectivity.

According to example embodiments, in a method of predicting a thickness profile of a layer, a plasma layer deposition apparatus is provided, wherein the plasma layer deposition apparatus includes a chamber, a substrate stage provided in the chamber and having a lower electrode, an upper electrode configured to form a plasma between the upper electrode and the lower electrode, and a source power circuit having a high frequency generator and an impedance matcher configured to supply a radio frequency (RF) power to the upper electrode, and an impedance controller configured to controller a current flowing to the lower electrode. A wafer is loaded on the substrate stage. An equivalent circuit model is derived, wherein the equivalent circuit model corresponds to a plasma system including the high frequency generator, the impedance matcher, the chamber, and the impedance controller. A sheath voltage based on the equivalent circuit model is determined, wherein the sheath voltage is applied to a space adjacent the loaded wafer by a matcher current from the impedance matcher. A selectivity as a ratio between thicknesses of each of plurality of deposition portions of the layer to be formed on the wafer is predicted by using relation between the determined sheath voltage and the selectivity.

According to example embodiments, in a method of predicting a thickness profile of a layer, a plasma layer deposition apparatus is provided, wherein the plasma layer deposition apparatus includes a chamber including a plasma region where a plasma is formed and a plurality of sheath regions surrounding the plasma region, a substrate stage provided in the chamber and having a lower electrode, an upper electrode configured to form the plasma between the upper electrode and the lower electrode, and a source power circuit having a high frequency generator and an impedance matcher configured to supply a radio frequency (RF) power to the upper electrode. A wafer is loaded on the substrate stage, wherein the wafer includes a first region having a first material and a second region having a second material. An equivalent circuit model is derived, wherein the equivalent circuit model corresponds to a plasma system including the high frequency generator, the impedance matcher, and the chamber. A sheath voltage based on the equivalent circuit model is determined, wherein the sheath voltage is applied to a space adjacent the loaded wafer by a matcher current from the impedance matcher. A selectivity of the layer as a ratio between a first thickness of a first deposition portion to be formed on the first region and a second thickness of the second deposition portion to be formed on the second region is predicted by using relation between the determined sheath voltage and the selectivity.

According to example embodiments, a plasma layer deposition apparatus includes a chamber including a process space and a gas supplier configured to supply a gas in the process chamber; a substrate stage provided in the chamber and configured to load a wafer, wherein the wafer includes a first region including a first material and a second region including a second material; a plasma control portion including a lower electrode provided in the substrate stage, an upper electrode provided on the chamber and configured to form a plasma between the lower electrode and the upper electrode, a source power circuit providing a high frequency generator and an impedance matcher configured to supply a radio frequency power to the upper electrode; and a controller including a simulation module configured to predict a selectivity of a layer deposited on the wafer, wherein the chamber includes a plasma region provided between the wafer and the upper electrode and a plurality of sheath regions surrounding the plasma region, wherein the simulation module of the controller is configured to derive an equivalent circuit model that is corresponds to a plasma system including the chamber, the substrate stage, the plasma control portion, the plasma region, the plurality of sheath regions, and the wafer and to predict the selectivity based on the equivalent circuit model, and wherein the selectivity is a ratio between a first thickness of a first deposition portion to be formed on the first region and a second thickness of the second deposition portion to be formed on the second region.

According to example embodiments, a plasma layer deposition apparatus may include a chamber, a substrate stage provided in the chamber and having a lower electrode, an upper electrode configured to form the plasma between the upper electrode and the lower electrode, and a source power circuit having a high frequency generator and an impedance matcher configured to supply a radio frequency (RF) power to the upper electrode. The chamber may include a plasma region where the plasma is formed and a plurality of sheath regions surrounding the plasma region.

According to example embodiments, in a method of predicting a thickness profile of a layer, the plasma layer deposition apparatus may be provided. A wafer may be loaded on the substrate stage, wherein the wafer includes a first region having a first material and a second region having a second material. An equivalent circuit model may be derived, wherein the equivalent circuit model corresponds to a plasma system including the high frequency generator, the impedance matcher, and the chamber. A sheath voltage based on the equivalent circuit model may be determined, wherein the sheath voltage is applied to a space adjacent the loaded wafer by a matcher current from the impedance matcher. And, a selectivity of a layer as a ratio between a first thickness of a first deposition portion to be formed on the first region and a second thickness of the second deposition portion to be formed on the second region may be predicted by using relation between the determined sheath voltage and the selectivity.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a cross-sectional view illustrating a plasma layer deposition apparatus according to one or more embodiments;

FIG. 2 is a flowchart illustrating a method of predicting a thickness profile of a layer by using a plasma layer deposition apparatus;

FIGS. 3 to 6 are diagrams illustrating a method of predicting a thickness profile of a layer by using a plasma layer deposition apparatus according to one or more embodiments; and

FIGS. 7 to 10 are diagrams illustrating a method of manufacturing a semiconductor device by using a plasma layer deposition apparatus according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

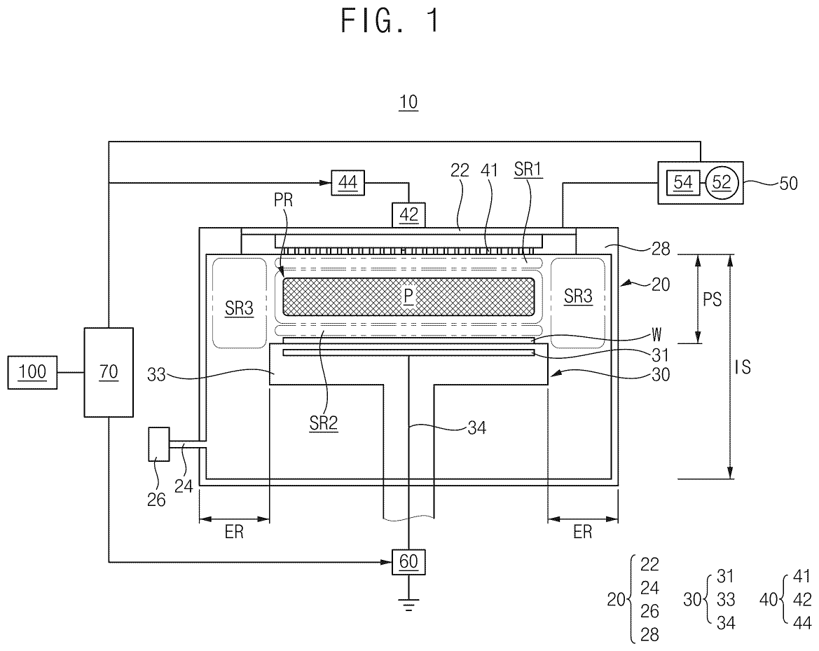

FIG. 1 is a cross-sectional view illustrating a plasma layer deposition apparatus according to one or more embodiments.

Referring to FIG. 1, a plasma layer deposition apparatus 10 may include a chamber 20 having an inner space IS, a substrate stage 30 disposed within the chamber 20 and configured to load a wafer W, a gas supplier 40 configured to inject a gas onto the wafer W, and a controller 70. The controller 70 may be connected to an upper electrode 22, a lower electrode 31 provided within the substrate stage 30, a source power circuit 50 electrically connected to the upper electrode 22 to supply RF power to the upper electrode 22, and an impedance controller 60 electrically connected to the lower electrode 31. Additionally, the controller 70 may further be connected to a simulation module 100.

A plasma enhanced chemical vapor deposition (PECVD) process may be performed by using the plasma layer deposition apparatus 10. For example, the plasma layer deposition apparatus 10 may be an apparatus configured to deposit a target layer on a substrate, such as a semiconductor wafer disposed within the chamber 20. For example, the substrate may include a silicon substrate, etc.

Additionally, the plasma layer deposition apparatus 10 may be a capacitively coupled plasma (CCP) processing apparatus. However, the plasma layer deposition apparatus 10 is not limited to thereto, and, for example, the plasma layer deposition apparatus 10 may be an inductively coupled plasma (ICP) processing apparatus, etc. The PECVD process may include a chemical process in which electromagnetic energy is applied to at least one precursor gas or precursor vapor to convert the precursor into reactive plasma. The PECVD process may be used to deposit, for example, an insulation layer on a semiconductor device such as a semiconductor wafer, not being limited thereto.

In one or more embodiments, the inner space IS of the chamber 20 may be a sealed interior space in which the plasma deposition process is performed on the wafer W. The chamber 20 may be a vacuum chamber. The chamber 20 may include a metal such as aluminum, stainless steel, etc.

A substrate stage 30 may be disposed in the inner space IS of the chamber 20 and configured to support the wafer W. For example, the substrate stage 30 may serve as a susceptor for supporting the wafer W. The substrate stage 30 may include an electrostatic chuck for electrostatically holding the wafer W at an upper portion thereof. As will be described later, the lower electrode 31 may be provided within the substrate stage 30 such that the lower electrode 31 is disposed under the wafer W.

A gate may be installed in a side wall of the chamber 20 and may be configured for entry and exit of the wafer W. The wafers W may be loaded and unloaded onto the substrate stage 30 through the gate.

An exhaust port 24 may be provided in a lower portion of the chamber 20. An exhaust portion 26 may be connected to the exhaust port 24 through an exhaust pipe. The exhaust portion 26 may include a vacuum pump, such as a turbomolecular pump, to control a pressure of a process space PS inside the chamber 20. Additionally, by-products of process and residual process gases generated within the chamber 20 may be discharged through the exhaust port 24.

The chamber 20 may include a cover 28 that is configured to cover an upper portion of the chamber 20. The cover 28 may seal the upper portion of the chamber 20.

The upper electrode 22 may be disposed on the upper portion of the chamber 20 such that the upper electrode 22 faces the lower electrode 31. The upper electrode 22 may be disposed within the cover 28. A process space PS between the upper electrode 22 and the lower electrode may be used as a plasma generation space. The upper electrode 22 may have a surface which faces the wafer W, which is supported on the substrate stage 30.

The inner space IS of the chamber 20 may include a process space PS disposed between the substrate stage 30 and the cover 28. The process space PS may be a space where the deposition process is performed. The process space PS may include a plasma region PR disposed between the upper electrode 22 and the lower electrode 31, and a plurality of sheath regions SR1, SR2, SR3 surrounding the plasma region PR. The plasma region PR may be a region in which the plasma P is formed. The plurality of sheath regions SR1, SR2, SR3 may include a first sheath region SR1 located between the plasma P and the cover 28, a second sheath region SR2 located between the plasma P and the substrate stage 30, and a third sheath region SR3 disposed on an edge region ER located between the substrate stage 30 and a side portion of the chamber 20.

For example, the plurality of sheath regions SR1, SR2 and SR3 may be regions where a voltage changes rapidly due to differences in movement speed between electrons and cations included in the plasma P when the plasma P is formed. For example, the plurality of sheath regions SR1, SR2 and SR3 may be formed in a region adjacent to the lower electrode 31, a region adjacent to the upper electrode 22, and a region adjacent to side walls of the chamber 20, respectively.

In one or more embodiments, the substrate stage 30 may include a substrate support 33 having a receiving surface on which the wafer W is seated, and the lower electrode 31 may be disposed under the wafer W and disposed inside the substrate support 33. The substrate stage 30 may further include a first signal line 34 that is configured to electrically connect the lower electrode 31 to the impedance controller 60, which will be described later.

In one or more embodiments, the gas supplier 40 may include a shower head 41, a flow controller 42 and a gas supply source 44. The gas supplier 40 may be an apparatus that is configured to supply a gas to the inner space IS of the chamber. The gas may include different gases in various desired ratio. For example, the gas may include titanium tetrachloride (TiCl₄), hydrogen (H₂), argon (Ar), etc.

The gas supply source 44 may store the different gases and be in fluid communication with the shower head 41. The gas introduced from the gas supply source 44 may be controlled at a desired flow rate by the flow controller 42.

In one or more embodiments, the source power circuit 50 may provide a plasma source power to the upper electrode 22. The source power circuit 50 may be electrically connected to the upper electrode 22 through a second signal line. For example, the source power circuit 50 may include plasma source elements, such as a high frequency generator 52 and an impedance matcher 54. The high frequency generator 52 may generate a radio frequency (RF) signal. The impedance matcher 54 may match an output impedance of the RF signal generated by the high frequency generator 52 to a chamber impedance X generated by a plasma layer deposition apparatus that does not include a high frequency generator. For example, the impedance matcher 54 may vary capacitors within the impedance matcher 54 so that maximum power is transferred to the plasma layer deposition apparatus 10.

In one or more embodiments, the impedance controller 60 may be electrically connected to the first signal line 34. The impedance controller 60 may regulate a strength of current flowing through the lower electrode 31, to control the location where the plasma P is formed. For example, the strength of the current flowing through the lower electrode 31 may be decreased to increase the strength of the current flowing through the side wall of the chamber 20. In this case, the plasma P may be concentrated to an edge region adjacent to the side wall of the chamber 20. In contrast, the strength of the current flowing to the lower electrode 31 may be increased to decrease the strength of the current flowing to the side wall of the chamber 20. In this case, the plasma P may be concentrated to a center of the chamber where the substrate stage 30 is provided.

Although the impedance controller 60 is shown in the figures, the plasma layer deposition apparatus 10 may not include the impedance controller 60.

In one or more embodiments, the controller 70 may be configured to change process conditions. The controller 70 may output control signals to the gas supplier 40 to control a flow rate of the gas injected into the chamber 20. The controller 70 may output control signals to the source power circuit 50 to control an RF power applied by the high frequency generator 52. The controller 70 may output a control signal to the impedance controller 60 to control an impedance of the impedance controller 60. The controller 70 may output a control signal to the exhaust portion 26 to control a pressure in the chamber 20.

For example, the controller 70 may include a simulation module 100. The simulation module 100 may be a module that is configured to predict a thickness profile (i.e., selectivity) of a layer formed by a deposition process by using the plasma layer deposition apparatus 10. The selectivity of the layer may a ratio of thicknesses of deposited portions of the layer. For example, a loaded wafer on the plasma layer deposition apparatus 10 may include a first region having a first material and a second region having a second material. The layer may include a first deposited portion formed on the first region and a second deposited portion formed on the second region. The first deposited portion on the first region may have a first thickness, and the second deposited portion formed on the second region may have a second thickness. In this case, a ratio of the first thickness to the second thickness may be the selectivity. For example, the first material may be silicon (Si). The second material may be an insulation material.

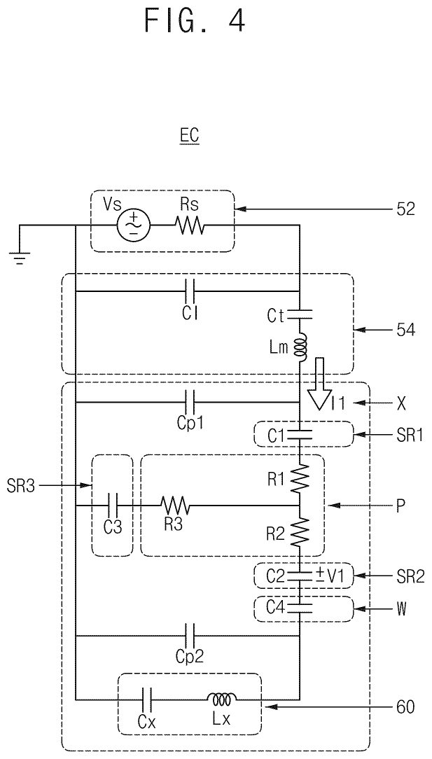

The simulation module 100 may derive an equivalent circuit model having an electrically equivalent relationship with a plasma system including the plasma layer deposition apparatus 10 and the loaded wafer W on the plasma layer deposition apparatus 10. From the equivalent circuit model, a sheath voltage V1 (refer to FIG. 4) across the second sheath region SR2 may be determined based on a matcher current I1 (refer to FIG. 4) introduced by the impedance matcher 54. The simulation module 100 may load stored data of the selectivity corresponding to the sheath voltage V1 and predict the selectivity by using a correlation between the sheath voltage V1 and the selectivity. For example, the simulation module 100 may determine a sheath voltage based on the equivalent circuit module, and a memory may store various pre-stored selectivities corresponding to various sheath voltages. Then, the simulation module 100 may compare the determined sheath voltage with the pre-stored selectivities, and use this comparison to predict the selectivity of the layer, based on the sheath voltage of the simulation potentially corresponding to the actual sheath voltage of the actual process performed by the plasma layer deposition apparatus 10 on the wafer W.

As described above, the plasma layer deposition apparatus 10 may include the chamber 20, the substrate stage 30 provided within the chamber 20 and that is configured to load the wafer W, the gas supplier 40 configured to inject the gas onto the wafer W, and the controller 70. The controller 70 may be connected to the upper electrode 22, the lower electrode 31 provided within the substrate stage 30, the source power circuit 50 electrically connected to the upper electrode, and the impedance controller 60 electrically connected to the lower electrode 31. Further, the controller 70 may be connected to the simulation module 100. The controller 70 may control the upper electrode 22, the lower electrode 31, the source power circuit 50, and the impedance controller 60 to function as a plasma controller. Furthermore, the controller 70 may be connected to the simulation module 100 and may be configured to, using the simulation module 100, to derive an equivalent circuit model having an electrically equivalent relationship with a plasma system including the plasma layer deposition apparatus 10 and the loaded wafer W on the plasma layer deposition apparatus 10.

The simulation module 100 may predict the selectivity of the layer formed by the deposition process using the plasma layer deposition apparatus 10. The simulation module 100 may derive the equivalent circuit model EC that is electrically equivalent to the plasma system including the plasma layer deposition apparatus 10 and the loaded wafer. From the equivalent circuit model, the sheath voltage V1 (refer to FIG. 4) across the second sheath region SR2 may be determined based on the matcher current I1 (refer to FIG. 4) introduced by the impedance matcher 54. Then, the simulation module 100 may load the stored data of the selectivity corresponding to the sheath voltage and predict the selectivity using correlation between the sheath voltage V1 and the stored selectivity.

Accordingly, the plasma layer deposition apparatus 10 may predict the selectivity without conducting actual deposition process experiments, to thereby reduce the experiment time and cost consumed by the process experiment.

Hereinafter, a method of predicting a thickness profile, i.e., a selectivity of a layer, using a plasma layer deposition apparatus 10 according to one or more embodiments will be described.

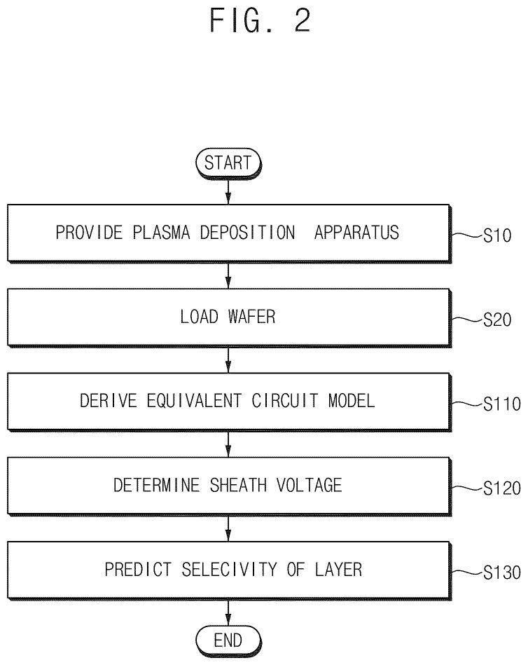

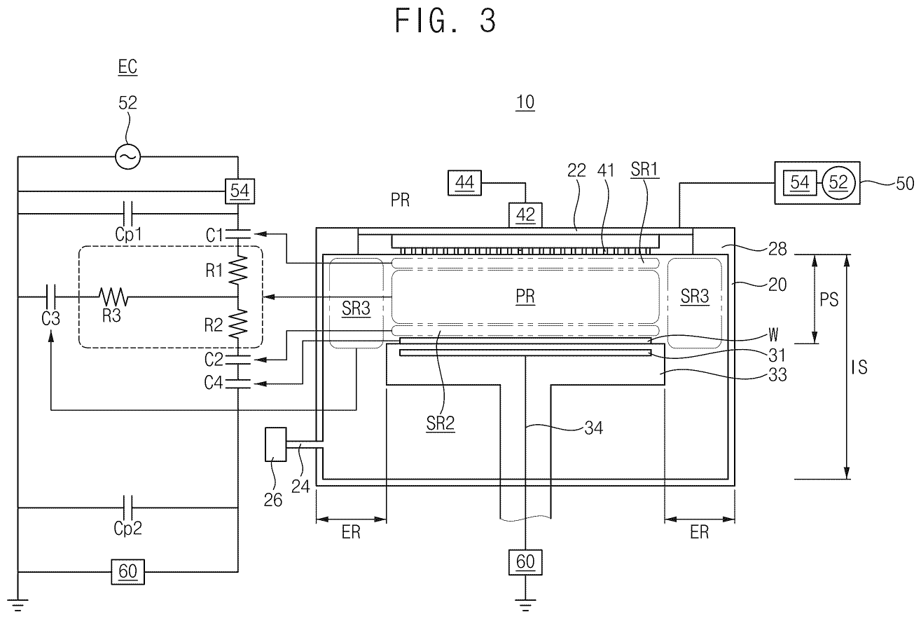

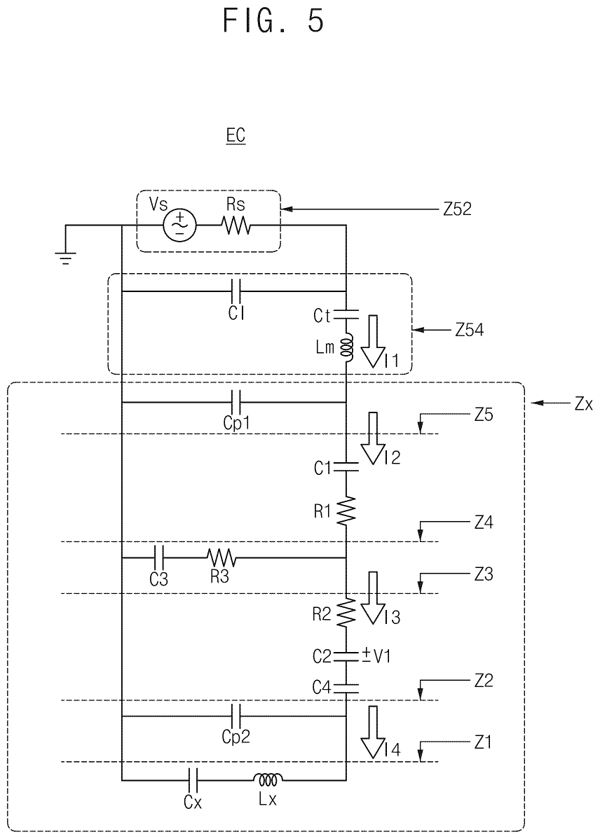

FIG. 2 is a flowchart illustrating a method of predicting layer according to one or more embodiments. FIGS. 3 and 4 are diagrams illustrating a plasma layer deposition apparatus and a corresponding equivalent circuit model according to one or more embodiments. FIG. 5 is a graph illustrating the correlation between a selectivity of a layer and a determined sheath voltage from the equivalent circuit model, according to one or more embodiments.

First, a plasma layer deposition apparatus 10 may be provided in operation S10. Then, a wafer W may be loaded onto a substrate stage 30 of the plasma layer apparatus 10 in operation S20. The wafer may include a first region having a first material and a second region having a second material. For example, the first material may be silicon (Si). Further, the second material may be an insulation material.

Since the plasma layer deposition apparatus is substantially the same as the plasma layer deposition apparatus 10 in accordance with embodiments described in FIG. 1, a repeated description of the same components may be omitted.

Referring to FIGS. 3 and 4, an equivalent circuit model EC corresponding to the plasma layer deposition apparatus 10 and the loaded wafer W may be derived in operation S110, and a sheath voltage V1 may be determined from the equivalent circuit model EC in operation S120. Thereafter, the correlation between the sheath voltage V1 and the pre-stored selectivity may be utilized to predict the sheath voltage V1 and the corresponding selectivity in operation S130.

First, in deriving the equivalent circuit model EC, the plasma layer deposition apparatus 10 and the loaded wafer W may be replaced with electrical elements having an electrically equivalent relationship to derive the equivalent circuit model EC. For example, the electrical elements may include capacitors, inductors, resistors, etc.

The high frequency generator 52 may be replaced by a power resistor Rs and a power voltage Vs, and the impedance matcher 54 may be replaced by a plurality of first inner capacitors Cl, Ct and at least one first inner inductor Lm. Further, the impedance controller 60 may be replaced by at least one second inner capacitor Cx and at least one second inner inductor Lx. For example, the plurality of first inner capacitors Cl, Ct may include a load capacitor Cl connected in parallel with the high frequency generator 52 and a regulating capacitor Ct connected in series with the high frequency generator 52. The at least one second inner capacitor Cx and the at least one second inner inductor Lx may be connected in series with each other.

The plasma region PR may be replaced with a plurality of plasma resistors R1, R2, R3. Further, the plurality of sheath regions SR1, SR2, SR3 may be replaced with a plurality of capacitors C1, C2, C3. For example, the first sheath region SR1 disposed between the plasma region PR and the upper electrode 22 may be replaced with a first capacitor C1, the second sheath region SR2 disposed between the plasma region PR and the loaded wafer W may be replaced with a second capacitor C2, and the third sheath region SR3 surrounding an outer side portion of the plasma region PR may be replaced with a third capacitor C3, in the equivalent circuit model EC.

The equivalent circuit model EC may include a plurality of parasitic capacitors to better simulate the electrical characteristics of the plasma system. The equivalent circuit EC may further include a first parasitic capacitor Cp1 and a second parasitic capacitor Cp2. For example, the first parasitic capacitor Cp1 may be connected in parallel with the high frequency generator 52 and the impedance matcher 54 within the equivalent circuit model EC. The first parasitic capacitor Cp1 may be an electrical element for simulating current, which flows from the upper electrode 22 to the chamber 20, to the plasma layer deposition apparatus 10. For example, the second parasitic capacitor Cp2 may be connected in parallel with the impedance controller 60 in the equivalent circuit model EC. The second parasitic capacitor Cp2 may be an electrical element for simulating current, which flows from the lower electrode 22 to the chamber 20, to the plasma layer deposition apparatus 10.

Further, the equivalent circuit model EC may include a fourth capacitor C4 corresponding to the loaded wafer W.

The equivalent circuit model EC may include a chamber portion X that does not include the high frequency generator 52 and the impedance matcher 54. An impedance value of the chamber portion X may be a chamber impedance Zx. A generator impedance Z52 may be an impedance of a portion corresponding to the high frequency generator 52 in the equivalent circuit model EC. A matcher impedance Z54 may be an impedance of a portion corresponding to the impedance matcher 54.

Next, a plurality of process input conditions may be simulated in the equivalent circuit model EC. The plurality of process input conditions may be processing conditions that are entered during an actual layer deposition process. The plurality of process input conditions may include a power supplied from the high frequency generator 52, an impedance magnitude of the impedance controller 60, and a process pressure inside the chamber 20.

For example, the power may be varied by changing the power voltage Vs of the high frequency generator 52 in the equivalent circuit model EC so that the power has an identical power to that which is supplied by the actual layer deposition process. Further, the impedance magnitude may be varied by changing values of the at least one second inner capacitor Cx and the at least one second inner inductor Lx so that the impedance magnitude has an identical impedance to that which is applied in the actual layer deposition process.

Further, the process pressure may be controlled by changing the values of the plurality of plasma resistors R1, R2, R3 and the plurality of capacitors C1, C2, C3 for simulating a tendency of change of the plasma according to a change of the process pressure in an actual chamber. For example, the tendency occurs when the process pressure increase. In case that the process pressure increase, a plasma density may increase because an amount of a supplied gas increases, but a plasma temperature may decrease because an energy of a particle of the supplied gas decreases. Thus, values of the plurality of plasma resistors R1, R2, and R3 may decrease, and values of the plurality of capacitors C1, C2, and C3 may increase. To simulate the tendency, the values of the plurality of plasma resistors R1, R2, R3 and the plurality of capacitors C1, C2, C3 may be adjusted.

Next, based on the equivalent circuit model EC, values of the plurality of electrical elements included in the equivalent circuit model EC, values of current flowing through each of the plurality of electrical elements, and values of voltages applied to each of the plurality of electrical elements may be determined.

For example, a plurality of circuit equations may be derived from the generator impedance Z52, the matcher impedance Z54, and the chamber impedance Zx of the equivalent circuit model EC. By determining the plurality of circuit equations using a computer program, values of the plurality of electrical elements included in the chamber portion X may be obtained.

However, the at least one second inner capacitor Cx and the at least one second inner inductor Lx may have values entered by the controller 70. Further, the power resistor Rs and the power voltage Vs may have preset values. For example, the power resistance may be 50 Ω. The power voltage may have a value entered by the controller 70.

The values of the plurality of first inner capacitors Cl and Ct and the at least one first inner inductor Lm may be determined according to a corresponding portion with the high frequency generator 52 and the chamber portion X. For example, the plurality of first inner capacitors Cl and Ct may be adjusted to maximize a power applied to the equivalent circuit model EC.

Next, a current value of the matcher current I1 introduced from the impedance matcher 54 may be determined by using the equivalent circuit model EC. From the matcher current I1, the sheath voltage V1 applied across the second capacitor C2 may be determined. For example, by using a current distribution law, a voltage value of the sheath voltage V1 may be determined from the value of the matcher current I1.

Then, a selectivity of a layer corresponding to the value of the sheath voltage V1 may be predicted by using the correlation between the sheath voltage V1 and the pre-stored selectivity. For example, the simulation module 100 of the plasma layer deposition apparatus 10 may store data of the sheath voltage V1 and the selectivity having a correlation relationship. The simulation module 100 may determine the sheath voltage V1 based on the equivalent circuit model EC. Subsequently, the sheath voltage V1 and the corresponding selectivity may be loaded from the stored data.

The selectivity of the layer may a ratio of thicknesses between deposited portions of a layer formed by the deposition process in a plasma layer deposition process. For example, a wafer, which is loaded onto the plasma layer deposition apparatus 10, may have a first region having a first material and a second region having a second material. The layer may include a first deposited portion formed on the first region and a second deposited portion formed on the second region. The first deposited portion on the first region may have a first thickness, and the second deposited portion formed on the second region may have a second thickness. In this case, the ratio of the first thickness to the second thickness may be the selectivity. For example, the first material may be silicon (Si). The second material may be an insulation material.

Referring to FIG. 5, the plurality of circuit equations may be derived from the equivalent circuit model EC. However, it will be appreciated that the plurality of circuit equations are exemplary and are not exclusive. Accordingly, the plurality of circuit equations may be replaced with other equations derived from the equivalent circuit model. For example, circuit equations may be analyzed in the frequency domain by being represented as complex numbers. An imaginary unit j may denote the square root of −1. An angular frequency w may be defined according to the power voltage Vs.

For example, a first to sixth equation may be derived from the equivalent circuit model by using impedance.

A first impedance Z1 may be expressed by Equation (1).

$$Z 1 = j * w * Lx + \frac{1}{j * w * Cx} \qquad ( 1 )$$

where Z1 is a value of the first impedance in the equivalent circuit model EC, and Lx is a value of the at least one second inner inductor of the impedance controller 60, and Cx is a value of the at least one second inner capacitor of the impedance controller 60.

A second impedance Z2 may be expressed by Equation (2).

$$Z 2 = \frac{Z 1 * \frac{1}{j * w * Cp 2}}{Z 1 + \frac{1}{j * w * Cp 2}} \qquad ( 2 )$$

where Z1 is a value of the first impedance in the equivalent circuit model EC, Z2 is a value of the second impedance in the equivalent circuit model EC, and Cp2 is a value of the second parasitic capacitor.

A third impedance Z2 may be expressed by Equation (3).

$$Z 3 = \frac{1}{j * w * C 4} + \frac{1}{j * w * C 2} + Z 2 + R 2 \qquad ( 3 )$$

where Z2 is a value of the second impedance in the equivalent circuit model EC, Z3 is a value of the third impedance in the equivalent circuit model EC, and C2 is a value of the second capacitor C2 for the second sheath region SR2, and C4 is a value of the fourth capacitor C4 for the loaded wafer W, and R2 is a value of one of the plurality of plasma resistors for the plasma region.

A fourth impedance Z4 may be expressed by Equation (4).

$$Z 4 = \frac{Z 3 * ( R 3 + \frac{1}{j * w * C 3} )}{Z 3 + ( R 3 + \frac{1}{j * w * C 3} )} \qquad ( 4 )$$

where Z3 is a value of the third impedance in the equivalent circuit model EC, and Z4 is a value of the fourth impedance in the equivalent circuit model EC, and R3 is a value of one of the plurality of plasma resistors for the plasma region, and C3 is a value of the third capacitor for the third sheath region SR3.

A fifth impedance Z5 may be expressed by Equation (5).

$$Z 5 = \frac{1}{j * w * C 1} + R 1 + Z 4 \qquad ( 5 )$$

where Z4 is a value of the fourth impedance in the equivalent circuit model EC, and Z5 is a value of the fifth impedance in the equivalent circuit model EC, and R1 is a value of one of the plurality of plasma resistors for the plasma region, and C1 is a value of the first capacitor for the first sheath region SR1.

The chamber impedance Zx may be expressed by Equation (6).

$$Zx = \frac{Z 5 * \frac{1}{j * w * Cp 1}}{Z 5 + \frac{1}{j * w * Cp 1}} \qquad ( 6 )$$

where Z5 is a value of the fifth impedance in the equivalent circuit model EC, and Zx is a value of the chamber impedance in the equivalent circuit model EC, and Cp1 is a value of the first parasitic capacitor.

Thus, by using first to sixth equation, the chamber impedance may be determined. For example, the at least one second inner inductor and the at least one second inner capacitor of the impedance controller 60 may be an input value

For example, a first to sixth equation may be derived from the equivalent circuit model by using current distribution law. According to the current distribution law, in circuits with parallel branches, total current may be distributed among the branches in inverse proportion to impedance of each branch.

A second current 12 may be expressed by Equation (7). For example, the second current may be a current through the first capacitor for the first sheath region SR1.

$$I 2 = \frac{\frac{1}{j * w * Cp 1}}{\frac{1}{j * w * Cp 1} + Z 5} * I 1 \qquad ( 7 )$$

where I1 is a value of the matcher current, and I2 is a value of the second current through the first capacitor, and Z5 is a value of the fifth impedance in the equivalent circuit model EC, and Cp1 is a value of the first parasitic capacitor.

A third current 13 may be expressed by Equation (8). For example, the third current may be a current through the second capacitor C2 for the second sheath region SR2.

$$I 3 = \frac{( R 3 + \frac{1}{j * w * C 3} )}{( R 3 + \frac{1}{j * w * C 3} ) + Z 3} * I 2 \qquad ( 8 )$$

where and I2 is a value of the second current through the first capacitor, and I3 is a value of the third current through the second capacitor C2, and R3 is a value of one of the plurality of plasma resistors for the plasma region, and C3 is a value of the third capacitor for the third sheath region SR3.

A fourth current I4 may be expressed by Equation (9). For example, the third current may be a current through the at least one second inner capacitor Cx and the at least one second inner inductor Lx of the impedance controller 60.

$$I 4 = \frac{\frac{1}{j * w * Cp 2}}{\frac{1}{j * w * Cp 2} + Z 1} * I 3 \qquad ( 9 )$$

where I3 is a value of the third current through the second capacitor C2, and I4 is a value of the fourth current through the at least one second inner capacitor Cx and the at least one second inner inductor Lx, and Z1 is a value of the first impedance in the equivalent circuit model EC, and Cp2 is a value of the second parasitic capacitor.

The sheath voltage V1 may be expressed by Equation (10).

$$V 1 = \vert \frac{1}{j * w * C 2} * I 3 \vert \qquad ( 10 )$$

where C2 is a value of the second capacitor C2 for the second sheath region SR2, and I3 is a value of the third current through the second capacitor C2, and V1 is a value of voltage across the second sheath region SR2.

Thus, by using the first to tenth equation, the sheath voltage V1 may be determined. For example, by using simulation software, the first to tenth equation may be analyzed to determine the sheath voltage V1. For example, the matcher current may be an input value

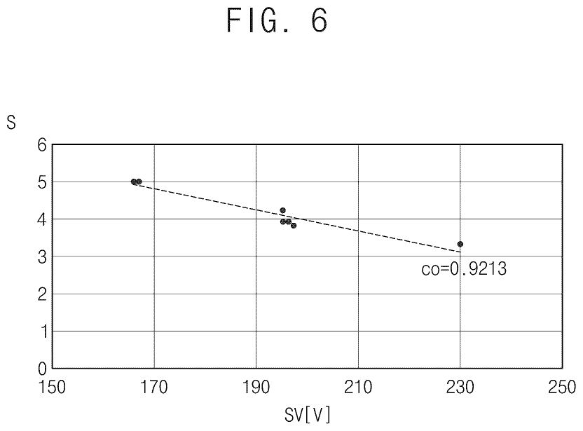

Referring to FIG. 6, the sheath voltage V1 determined by the method of predicting the selectivity in accordance with one or more embodiments and the selectivity of the layer formed by the plasma layer deposition apparatus 10 may have a correlation with each other. In the graph of FIG. 6, a horizontal axis SV may represent a voltage value of the determined sheath voltage V1 and a vertical axis S may represent a measured value of the selectivity of the layer measured by experiment.

TABLE 1

| | Process | | | Experimental | | Simulation | |
|---|---|---|---|---|---|---|---|
| | Condition | | | Result | | Result | |
| | Pressure | Power | | I₁ | | I₁ | SV |
| | [Torr] | [W] | Z₆₀[Ω] | [A] | S | [A] | [V] |
| 1 | 5 | 300 | 70 | 1.51 | 3.3 | 1.78 | 230 |
| 2 | 5 | 200 | 70 | 1.3 | 3.8 | 1.53 | 197 |
| 3 | 6 | 200 | 70 | 1.32 | 4.2 | 1.50 | 195 |
| 4 | 6 | 150 | 70 | 1.22 | 5 | 1.34 | 167 |
| 5 | 9 | 200 | 70 | 1.45 | 5 | 1.43 | 166 |
| 6 | 5 | 200 | 60 | 1.32 | 3.9 | 1.53 | 196 |
| 7 | 5 | 200 | 55 | 1.32 | 3.9 | 1.52 | 195 |

| | | |
|---|---|---|
| Correlation Coefficient (R²) | 0.92 | 0.70 |

In the process conditions in Table 1, “pressure” may be the pressure inside the chamber 20, “power” may be the power applied by the high frequency generator 52, and “Z60” may be the impedance of the impedance controller 60. In the results in Table 1, “I1” may be an actual measurement of the matcher current I1 introduced by the impedance matcher 54 of the plasma layer deposition apparatus 10, and “S” may be a ratio of the thicknesses of the deposited portions of the layer (e.g., the first deposited portion on the first region and the second deposited portion formed on the second region) formed by the deposition process when the deposition process is performed by the plasma layer deposition apparatus 10. In the simulation of Table 1, “I1” may be a determined value of the matcher current I1 measured in the equivalent circuit EC, and “SV” may be a determined value of the sheath voltage V1 measured in the equivalent circuit EC.

The graph of FIG. 6 illustrates the experimental results and the simulation results of Table 1. For example, the graph of FIG. 6 illustrates a correlation between the measured value S of the selectivity obtained by the experiment in Table 1 and the determined value SV of the sheath voltage obtained by the simulation in Table 1.

The correlation coefficient CO between the determined voltage value SV of the sheath voltage V1 and the measured value S of the selectivity of the layer may be ‘0.9213’. The correlation coefficient may have a value within the range of ‘0’ to ‘1’ as an indicator of a relevance between two values. For example, the closer the correlation coefficient is to ‘1’, the more related the two values are, and the closer the correlation coefficient is to ‘0’, the less related the two values are. Since the correlation coefficient CO has a value relatively close to ‘1’, there may be a relatively high correlation between the voltage value SV of the determined sheath voltage V1 and the measured value S of the selectivity of the layer.

Thus, from the graph of FIG. 6, the method of predicting a thickness profile of a layer in accordance with one or more embodiments effectively predicts the selectivity of a layer.

As described above, in the method of predicting layer, the plasma layer deposition apparatus 10 may be provided. The wafer W may be loaded onto the substrate stage 30 of the plasma layer deposition apparatus 10, where the wafer includes the first region having the first material and the second region having the second material. The selectivity may be predicted by performing a simulation for a system including a simulated plasma layer deposition apparatus, where the selectivity is the ratio of the first thickness of the first deposition portion to be formed on the first region to the second thickness of the second deposition portion to be formed on the second region.

Accordingly, the method predicting layer by using the simulated plasma layer deposition apparatus may predict the selectivity of the layer without performing actual deposition process experiments, thereby reducing the experiment time and cost consumed by process experiments.

Hereinafter, a method of manufacturing semiconductor including the method of predicting a thickness profile of a layer in accordance with one or more embodiments will be described.

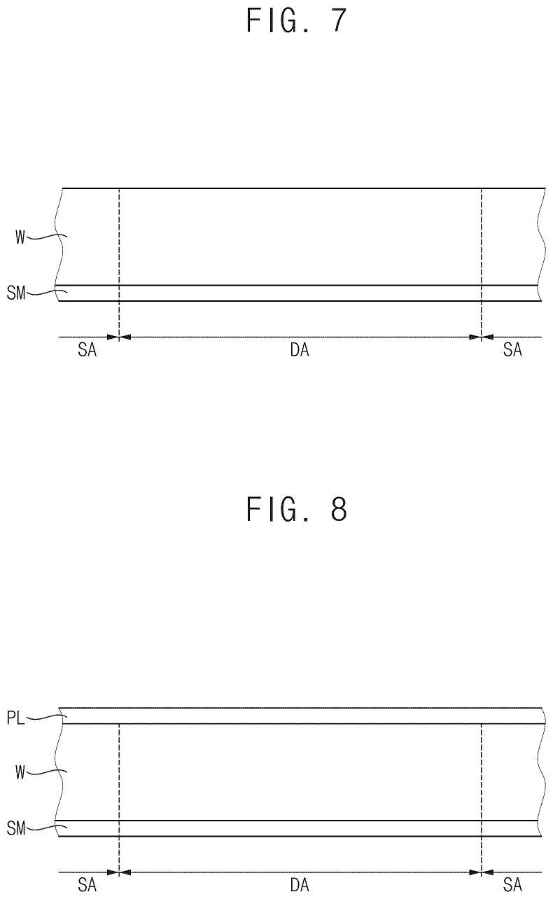

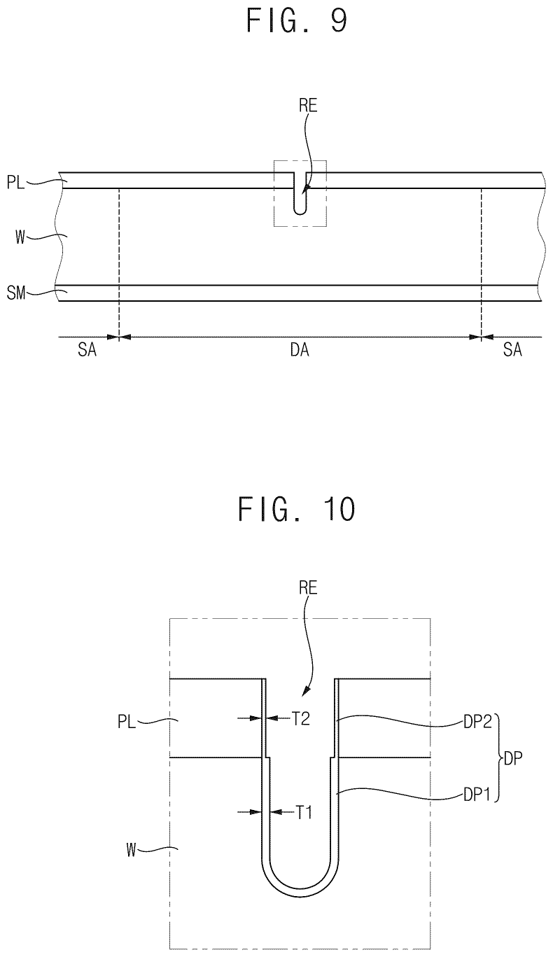

FIG. 7 is a cross-sectional view illustrating that a wafer according to one or more embodiments. FIG. 8 is a cross-sectional view illustrating that an insulation layer is formed on the wafer in FIG. 7 according to one or more embodiments. FIG. 9 is a cross-sectional view illustrating that a recess is formed on the insulation layer in FIG. 8 according to one or more embodiments. FIG. 10 is a cross-sectional view illustrating a first deposition portion and a second deposition portion are formed on the recess in FIG. 9 according to one or more embodiments.

Referring to FIG. 7, a wafer W may be provided on a support member SM, where the wafer may include a plurality of die regions DA and a scribe lane region SC surrounding the plurality of die regions DA. For example, each of the plurality of die regions DA may be regions on which a semiconductor is formed. The scribe lane region SC may be a region that is removed by a sawing process to separate semiconductors from the wafer.

Referring to FIG. 8, a deposition process may be performed to form the insulation layer PL on a surface of the wafer W. For example, the deposition process may be a dry etching process such as CVD, etc.

Referring to FIG. 9, a photolithography process may be performed on the insulation layer PL to form recesses R on each of the plurality of die regions DR. The recesses R may be formed by partially removing the insulation layer PL and a portion of the wafer W provided under the insulation layer PL. Through the recesses R, at least a portion of the wafer W may be exposed.

For example, a photoresist layer may be applied on the insulation layer PL, an exposure process may be performed to emit light on the photoresist layer, and a development process may be performed to remove a portion of the photoresist layer to form a photoresist pattern that exposes a region where the recesses R is to be formed. Thereafter, an etching process may be performed on the photoresist pattern to form the recesses R.

Referring to FIG. 10, the wafer W may be loaded onto a plasma layer deposition apparatus (illustrated in FIG. 1), and a simulation (illustrated in FIGS. 2 to 5) may be performed on the plasma layer deposition apparatus and the loaded wafer W to predict a thickness profile, i.e., a selectivity of a layer. Thereafter, a plasma layer deposition process may be performed on the loaded wafer W to form a deposition layer DP including a first deposition portion DP1 having a first thickness T1 and a second deposition portion DP2 having a second thickness T2. The first thickness T1 and second thickness T2 may have a predicted selectivity.

For example, the wafer W and the insulation layer PL may include different materials. The wafer W may include a first material and the insulation layer PL may include a second material. For example, the first material may be silicon (Si). A ratio of the first thickness T1 of the first deposited portion DP1 to be deposited on the wafer W and the second thickness T2 of the second deposited portion DP2 to be deposited on the insulation layer PL may be predicted.

For example, the plasma layer deposition process may be a PECVD process.

Accordingly, the method of predicting a thickness profile of a layer using the plasma layer deposition apparatus may predict the selectivity of the layer without conducting actual deposition process experiments, thereby reducing an experiment time and an experiment cost consumed by a process experiment.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

1. A method of predicting a thickness profile of a layer, the method comprising:
providing a plasma layer deposition apparatus, wherein the plasma layer deposition apparatus comprises a substrate stage provided in a chamber, a lower electrode, an upper electrode, and a source power circuit comprising a high frequency generator and an impedance matcher configured to supply a radio frequency (RF) power to the upper electrode;
loading a wafer on the substrate stage, wherein the wafer comprises a first region having a first material and a second region having a second material;
deriving an equivalent circuit model of a plasma system simulating the plasma layer deposition apparatus;
determining a sheath voltage based on the equivalent circuit model, the sheath voltage corresponding to a voltage applied to a space adjacent to the wafer by a matcher current from the impedance matcher; and
predicting a selectivity of the layer as a ratio between a first thickness of a first deposition portion on the first region and a second thickness of a second deposition portion on the second region based on a correlation between the determined sheath voltage and a pre-stored selectivity value.

2. The method of claim 1, wherein the determining the sheath voltage comprises:
controlling values of a plurality of circuit elements of the equivalent circuit model to simulate process conditions of the plasma layer deposition apparatus;
determining the matcher current from the equivalent circuit model based on a first impedance corresponding to a simulated high frequency generator, a second impedance corresponding to a simulated impedance matcher, and a third impedance corresponding to a simulated chamber portion that does not include a high frequency generator or an impedance matcher; and
determining the sheath voltage from the equivalent circuit model based on the matcher current.

3. The method of claim 2, wherein the controlling values of the plurality of circuit elements comprises simulating a pressure in the chamber and the RF power supplied from the high frequency generator, with the equivalent circuit model.

4. The method of claim 1, wherein the predicting the selectivity comprises:
storing data about the sheath voltage and the pre-stored selectivity value; and
deriving the selectivity based on the stored data.

5. The method of claim 1, wherein the equivalent circuit model simulates a plasma region where plasma is formed in the chamber and a plurality of sheath regions surrounding the plasma region.

6. The method of claim 5, wherein the deriving the equivalent circuit model comprises:
simulating the high frequency generator with a power resistor and a power voltage; and
simulating the impedance matcher with a plurality of first inner capacitors and at least one first inner inductor.

7. The method of claim 5, wherein the deriving the equivalent circuit model comprises:
simulating the plasma region with a plurality of plasma resistors; and
simulating the plurality of sheath regions with a plurality of capacitors.

8. The method of claim 7, wherein the simulating the plurality of sheath regions with the plurality of capacitors comprises:
simulating a first sheath region between the plasma region and the upper electrode with a first capacitor;
simulating a second sheath region between the plasma region and the wafer with a second capacitor; and
simulating a third sheath region surrounding an outer side portion of the plasma region with a third capacitor.

9. The method of claim 1, wherein the plasma layer deposition apparatus further comprises an impedance controller configured to control a current flowing to the lower electrode, and
wherein the equivalent circuit model simulates the impedance controller.

10. The method of claim 9, wherein the deriving the equivalent circuit model comprises simulating the impedance controller with at least one second inner capacitor and at least one second inner inductor.

11. A method of predicting a thickness profile of a layer, the method comprising:
providing a plasma layer deposition apparatus, wherein the plasma layer deposition apparatus comprises a chamber, a substrate stage provided in the chamber, a lower electrode, an upper electrode, a source power circuit comprising a high frequency generator and an impedance matcher configured to supply a radio frequency (RF) power to the upper electrode, and an impedance controller configured to control a current flowing to the lower electrode;
loading a wafer on the substrate stage;
deriving an equivalent circuit model of a plasma system simulating the plasma layer deposition apparatus;
determining a sheath voltage based on the equivalent circuit model, the sheath voltage corresponding to a voltage applied to a space adjacent to the wafer by a matcher current from the impedance matcher; and
predicting a selectivity as a ratio between thicknesses of each of plurality of deposition portions of the layer to be formed on the wafer based on a correlation between the determined sheath voltage and a pre-stored selectivity value.

12. The method of claim 11, wherein the determining the sheath voltage comprises:
controlling values of a plurality of circuit elements of the equivalent circuit model to simulate process conditions of the plasma layer deposition apparatus;
determining the matcher current from the equivalent circuit model based on a first impedance corresponding to a simulated high frequency generator, a second impedance corresponding to a simulated impedance matcher, and a third impedance corresponding to a simulated chamber portion that does not include a high frequency generator or an impedance matcher; and
determining the sheath voltage from the equivalent circuit model based on the matcher current.

13. The method of claim 12, wherein the controlling values of the plurality of circuit elements comprises simulating a pressure in the chamber, the RF power supplied from the high frequency generator, and an impedance value of the impedance controller, with the equivalent circuit model.

14. The method of claim 11, wherein the predicting the selectivity comprises
storing data about the sheath voltage and the pre-stored selectivity value; and
deriving the selectivity based on the stored data.

15. The method of claim 11, wherein the equivalent circuit model simulates a plasma region where plasma is formed in the chamber and a plurality of sheath regions surrounding the plasma region.

16. The method of claim 15, wherein the deriving the equivalent circuit model comprises:
simulating the high frequency generator with a power resistor and a power voltage;
simulating the impedance matcher with a plurality of first inner capacitors and at least one first inner inductor; and
simulating the impedance controller with at least one second inner capacitor and at least one second inner inductor.

17. The method of claim 15, wherein the deriving the equivalent circuit model comprises:
simulating the plasma region with a plurality of plasma resistors; and
simulating the plurality of sheath regions with a plurality of capacitors.

18. The method of claim 17, wherein the simulating the plurality of sheath regions with the plurality of capacitors comprises:
simulating a first sheath region between the plasma region and the upper electrode with a first capacitor;
simulating a second sheath region between the plasma region and the wafer with a second capacitor; and
simulating a third sheath region surrounding an outer side portion of the plasma region with a third capacitor.

19. The method of claim 11, wherein the wafer comprises a first region comprising a first material and a second region comprising a second material, and
wherein the predicting the selectivity comprises predicting the selectivity as a ratio between a first thickness of a first deposition portion on the first region and a second thickness of a second deposition portion on the second region.

20. A method of predicting a thickness profile of a layer, the method comprising:
providing a plasma layer deposition apparatus, wherein the plasma layer deposition apparatus comprises a chamber comprising a plasma region where plasma is formed and a plurality of sheath regions surrounding the plasma region, a substrate stage in the chamber, a lower electrode, an upper electrode configured, and a source power circuit comprising a high frequency generator and an impedance matcher configured to supply a radio frequency (RF) power to the upper electrode;
loading a wafer on the substrate stage, wherein the wafer comprises a first region having a first material and a second region having a second material;
deriving an equivalent circuit model of a plasma system simulating the plasma layer deposition apparatus;
determining a sheath voltage based on the equivalent circuit model, the sheath voltage corresponding to a voltage applied to a space adjacent to the wafer by a matcher current from the impedance matcher; and
predicting a selectivity of the layer as a ratio between a first thickness of a first deposition portion to be formed on the first region and a second thickness of a second deposition portion to be formed on the second region based on the determined sheath voltage and a pre-stored selectivity value.

21.-29. (canceled)
